(19) United States
(12) Patent Application Publication
(10) Pub. No.: US 2023/0343900 A1
(43) Pub. Date: Oct. 26, 2023

(54) LIGHT-EMITTING DIODE AND LIGHT-EMITTING DEVICE

(71) Applicant: Quanzhou Sanan Semiconductor Technology Co., Ltd., Quanzhou (CN)

(72) Inventors: Yun ZHANG, Quanzhou (CN); Ningning ZHAN, Quanzhou (CN); Qiaotian WU, Quanzhou (CN); Shihwei LIN, Quanzhou (CN); Huili FAN, Quanzhou (CN); Shutian QIU, Xiamen (CN)

(21) Appl. No.: 18/193,409

(22) Filed: Mar. 30, 2023

(30) Foreign Application Priority Data
Apr. 20, 2022 (CN) 202210418925.2

(51) Int. Cl. H01L 33/40; H01L 33/38; H01L 33/62; H01L 33/12

(52) U.S. Cl. CPC H01L 33/382; H01L 33/12; H01L 33/40; H01L 33/62

(57) ABSTRACT

A light-emitting diode includes a semiconductor epitaxial structure and an electrode structure. The electrode structure includes an ohmic contact layered unit disposed on the semiconductor epitaxial structure, and a wire bonding layered unit disposed on the ohmic contact layered unit. The wire bonding layered unit includes at least one stress buffer portion and a pad portion disposed on the at least one stress buffer portion. The stress buffer portion includes at least two stress buffer layers and an electrode metal layer disposed therebetween. Each of the stress buffer layers has a hardness greater than that of the pad portion. A light-emitting device is also disclosed.

### CROSS-REFERENCE TO RELATED APPLICATION

This application claims priority to Chinese Invention Patent Application No. 202210418925.2, filed on Apr. 20, 2022, which is incorporated herein by reference in its entirety.

### FIELD

The disclosure relates to a semiconductor light-emitting device, and more particularly to a light-emitting diode (LED) and a light-emitting device including the same.

### BACKGROUND

A light-emitting diode (LED) is a semiconductor light-emitting device typically made of a semiconductor material such as GaN, GaAs, GaP, GaAsP, AlGalnP, etc., and includes a PN junction for light emitting. In forward bias, electrons in the semiconductor may travel from an N-region into a P region, and holes may travel from the P region into the N region, such that a portion of minority carriers having entered the opposite region (e.g., the electrons in the P region) may recombine with majority carriers (e.g., the holes in the P region) to emit light. LEDs offer advantages such as high light-emission intensity, fast response, small size, long lifespan, etc., and are thus considered to be one of the most promising light sources currently.

A conventional LED includes a substrate, an epitaxial structure, and an electrode structure which generally includes a pad layer and an ohmic contact layer. The ohmic contact layer is configured to form electrical connection, i.e., ohmic contacts, between the electrode structure and a semiconductor layer of the epitaxial structure. The pad layer serves as a wire-bonding pad for subsequent packaging and wire-bonding procedures, and for providing protection to underlying elements of the LED. The pad layer is generally made of gold. However, problems such as wire-bonding abnormalities or layer crack/peeling occur frequently during the wire bonding procedure.

### SUMMARY

Therefore, an object of the disclosure is to provide a light-emitting diode and a light-emitting device that can alleviate at least one of the drawbacks of the prior art.

According to one aspect of the disclosure, the light-emitting diode includes a semiconductor epitaxial structure and an electrode structure. The semiconductor epitaxial structure includes a first semiconductor layer, an active layer and a second semiconductor layer arranged in such order. The electrode structure is disposed on the semiconductor epitaxial structure and includes an ohmic contact layered unit disposed on the semiconductor epitaxial structure, and a wire bonding layered unit disposed on the ohmic contact layered unit. The wire bonding layered unit includes at least one stress buffer portion and a pad portion disposed on the at least one stress buffer portion. The at least one stress buffer portion includes a first stress buffer layer, a first electrode metal layer and a second stress buffer layer which are stacked on one another in such order on the ohmic contact layered unit. Each of the first and second stress buffer layers has a hardness greater than that of the pad portion.

According to another aspect of the disclosure, the light-emitting device includes at least one aforementioned light-emitting diode.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1A is a schematic view illustrating a light-emitting diode in a horizontal configuration according to the disclosure.

FIG. 1B is a schematic view illustrating a light-emitting diode in a vertical configuration according to the disclosure.

FIG. 1C is a schematic view illustrating another light-emitting diode in a horizontal configuration according to the disclosure.

FIG. 1D is a schematic view illustrating another light-emitting diode in a vertical configuration according to the disclosure.

FIG. 2 is a schematic view illustrating a first embodiment of an electrode structure according to the disclosure.

FIG. 3 is a schematic view illustrating a second embodiment of the electrode structure according to the disclosure.

FIG. 4 is a schematic view illustrating a third embodiment of the electrode structures according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “horizontal,” “vertical,” “transverse,” “center,” “top,” “bottom,” “upper,” “lower,” “left,” “right,” “inner,” “outer,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly. In addition, the terms “first,” “second,” “third,” etc., are used for descriptive purposes only and are not to be construed as indicating or implying relative importance or as implicitly specifying the number of elements. Thus, for an element with one of these terms preceding it, the disclosure encompasses the possibility that there may be one or more such elements. In this disclosure, unless otherwise specified, “a plurality of,” “plural” or the like means two or more. In addition, the terms “includes,” “comprises” or the like or any variation thereof does not exclude the presence of additional elements not specifically disclosed.

In this disclosure, it is to be noted that, unless otherwise expressly specified, the terms “mount,” “connect,” “couple,” “install,” etc., are to be interpreted in a broad sense, e.g., as encompassing fixed connection, removable connection, or integrated connection (e.g., one-piece formation), as encompassing mechanical connection or electrical or signal connection, and as encompassing direct connection or indirect connection through an intermediary.

The present disclosure provides a light-emitting diode (LED) and a light-emitting device including the same.

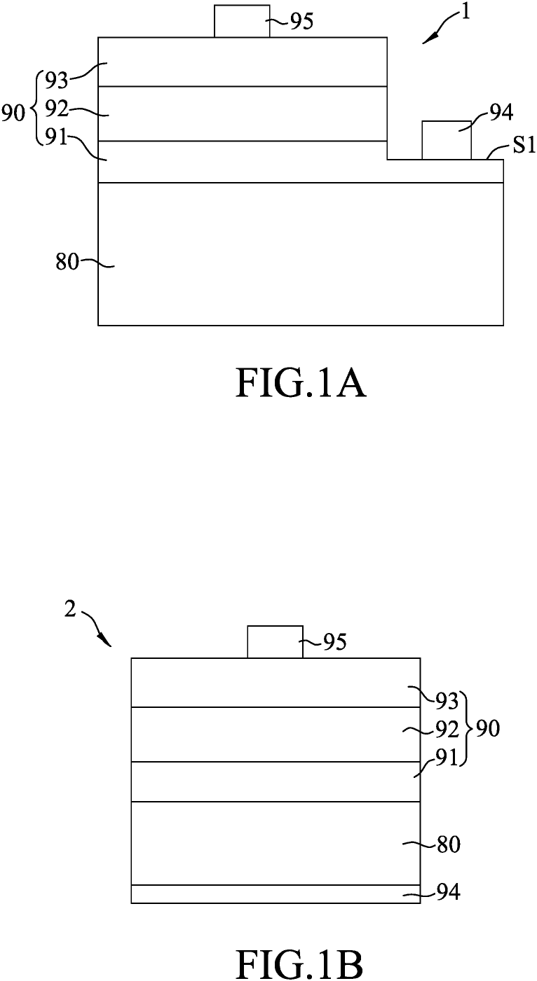

FIG. 1A is a schematic view illustrating an embodiment of a light-emitting diode 1 in a horizontal configuration in accordance with the disclosure. The LED 1 includes a supporting substrate 80, a semiconductor epitaxial structure 90, a first electrode 94, and a second electrode 95. The supporting substrate 80 may be made of an insulating and transparent material, such as sapphire, GaN, GaAs, GaP, etc. The semiconductor epitaxial structure 90 includes a first semiconductor layer 91 having a first polarity, an active layer 92, and a second semiconductor layer 93 having a second polarity opposite to the first polarity. The first semiconductor layer 91 is, for example, an N-type semiconductor layer disposed on the supporting substrate 80. The active layer 92 is disposed on the first semiconductor layer 91. The active layer 92 may include a single quantum well structure or a multiple quantum well structure (MQW). The MQW includes quantum well layers and quantum barrier layers that are alternately arranged. The second semiconductor layer 93 is, for example, a P-type semiconductor layer disposed on the active layer 92.

Each of the first semiconductor layers 91, the active layer 92, and the second semiconductor layer 93 may include a lll-V compound semiconductor material, such as GaP, GaAs, or GaN, etc. A wavelength of light emitted from the LED 1 is determined by a material composition and a thickness of the well layers of the active layer 92. In certain embodiments, the active layer 92 includes AlGalnP and emits red light, and therefore, the LED 1 is a red LED. In certain embodiments, the active layer 92 includes AlGaAs, InGaAs, etc, and thus emits infrared light, and thus, the LED 1 is an infrared LED. In some embodiments, the LED 1 may be configured to emit light having a wavelength ranging from 550 nm to 950 nm. The first semiconductor layer 91, the active layer 92, and the second semiconductor layer 93 may be manufactured by a conventional epitaxy process, such as organic metal chemical vapor deposition (MOCVD), molecular beam epitaxy (MBE), or a hydride vapor phase epitaxy (HVPE).

In the LED 1, the first semiconductor layer 91 has a portion (S1) that is not covered by the active layer 92 and the second semiconductor layer 93. The first electrode 94 is disposed on the portion (S1), and the second electrode 95 is disposed on the second semiconductor layer 93.

FIG. 1B is a schematic view illustrating an embodiment of an LED 2 in a vertical configuration according to the disclosure. The LED 2 has a structure similar to that of the LED 1 illustrated in FIG. 1A, except that, in this embodiment, the supporting substrate 80 of the LED 2 is an electrically conductive substrate. In this embodiment, the semiconductor epitaxial structure 90 is grown on a growth substrate, such as GaAs, and is then removed from the growth substrate and bonded to the supporting substrate 80 (i.e., electrically conductive substrate) instead, which may avoid light absorption by the growth substrate. Moreover, in this embodiment, the second electrode 95 is disposed on the electrically conductive substrate opposite to the semiconductor epitaxial structure 90. The electrically conductive substrate includes a metal material, such as Cu, Al, In, Sn, Zn, W, or combinations thereof, or includes a semiconductor material, such as Si, SiC, GaN, etc.

Referring to FIGS. 1C and 1D, in certain embodiments, the LEDs 1 and 2 may further include a transparent conductive layer 96 which is disposed between the second semiconductor layer 93 and the second electrode 95 for current spreading so that the distribution of current may be more uniform, thereby improving the light-emitting performance of the LEDs 1 and 2. The transparent conductive layer 96 may be made of a transparent conductive material. The LEDs 1 and 2 may have improved reliability when the transparent conductive layer 96 is made of a transparent conductive oxide material. The transparent conductive oxide material for the transparent conductive layer 96 may include, but is not limited to, indium tin oxide (ITO), indium zinc oxide (lZO), indium oxide (InO), tin oxide (SnO), cadmium tin oxide (CTO), antimony oxide (ATO), aluminum zinc oxide (AZO), zinc tin oxide (ZTO), gallium doped zinc oxide (GZO), tungsten doped indium oxide (IWO), zinc oxide (ZnO), and combinations thereof.

In addition, the first electrode 94 and/or the second electrode 95 according to the present disclosure are designed to include an electrode structure described below so as to diminish abnormalities in a wire-bonding procedure.

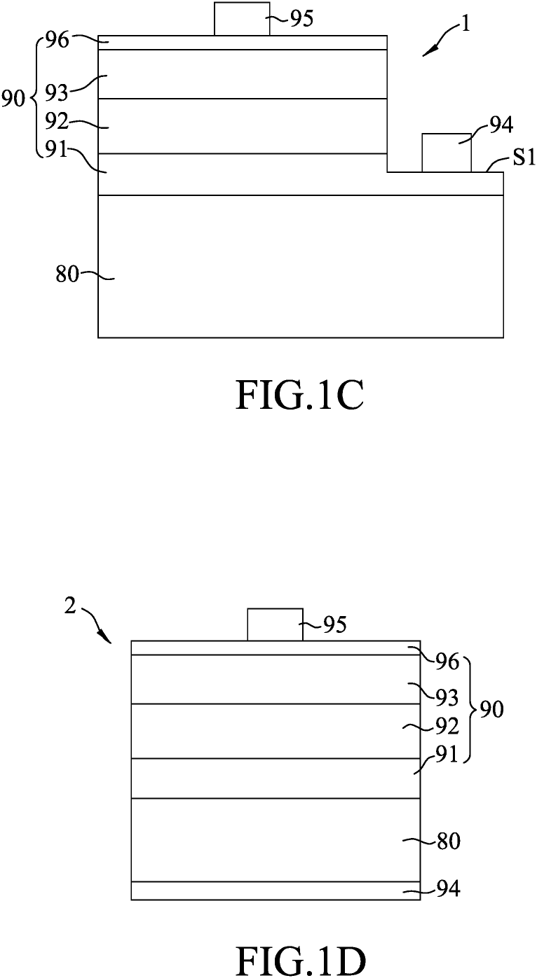

FIG. 2 shows a first embodiment of an electrode structure 3 for the first electrode structure 94 and/or the second electrode structure 95 according to the present disclosure. The electrode structure 3 may be prepared by an evaporation process. The electrode structure 3 includes an ohmic contact layered unit 10 for forming ohmic contacts with the semiconductor epitaxial structure 90, and a wire bonding layered unit 20 disposed on the ohmic contact layered unit 10 opposite to the semiconductor epitaxial structure 90. In certain embodiments, the electrode structure 3 further includes an adhesion layer 30 and a barrier layer 40. The adhesion layer 30 is disposed between the ohmic contact layer 10 and the semiconductor epitaxial structure 90 for improving the adhesion between the ohmic contact layer 10 and the semiconductor epitaxial structure 90. The barrier layer 40 is disposed between the wire bonding layered unit 20 and the ohmic contact layered unit 10 for separating the wire bonding layered unit 20 and the ohmic contact layered unit 10, so as to prevent materials of the ohmic contact layered unit 10 and the wire bonding layered unit 20 from mutual diffusion, for example, to prevent any material in the ohmic contact layered unit 10 from diffusing into the wire bonding layered unit 20. In addition, the barrier layer 40 may improve the adhesion between the ohmic contact layered units 10 and the wire bonding layered units 20.

The wire bonding layered unit 20 includes at least one stress buffer portion 21 and a pad portion 22 disposed on the at least one stress buffer portion 21. A thickness of the wire bonding layered unit 20 may vary based on the size of the LED 1, 2 and a force that the LED needs to withstand during the wire bonding process. The thickness of the wire bonding layered unit 20 of the electrode structure 3 may be more than 0.5 times a total thickness of the electrode structure 3. In certain embodiments, the thickness of the wire bonding layered unit 20 of the electrode structure 3 is 0.55 to 0.97 times the total thickness of the electrode structure 3, for example, 0.55 to 0.8 times, 0.8 to 0.9 times, or 0.9 to 0.97 times. In certain embodiments, the thickness of the wire bonding layered unit 20 ranges from 10,000 angstroms (Å) to 40,000 Å, e.g., from 12,000 Å to 40,000 Å. The wire bonding layered unit 20 is the main structure in the electrode structure 3 that bears the force and pressure encountered during the wire bonding process e.g., a soldering process.

The pad portion 22 is an outermost layer of the electrode structure 3, and is directly subjected to external force and serves as an external contact for the electrode structure 3. In certain embodiments, the pad portion 22 has a thickness which is of more than 50% of the total thickness of the wire bonding layered unit 20, for example, 75% to 80%. The thickness of the pad portion 22 may range from 10,000 Å to 30,000 Å. The pad portion 22 provides both physical and chemical protections for the electrode structure 3. The pad portion 22 may be made of a material exhibiting good stability and ductility, including, for example, Au, Al, Cu or alloys (e.g., AlCu) thereof.

The stress buffer portion 21 is provided between the pad portion 22 and the barrier layer 40 for enhancing the connections between the wire bonding layered unit 20 and the barrier layer 40. As shown in FIG. 2, the stress buffer portion 21 includes a first stress buffer layer 24a, a first electrode metal layer 23, and a second stress buffer layer 24b which are stacked on one another in such order. A hardness of each of the first stress buffer layer 24a and the second stress buffer layer 24b is greater than that of the pad portion 22. In the wire bonding procedure, the bonding force exerted on the pad portion 22 may lead to partial deformation of the pad portion 22. The stress buffer portion 21, due to having greater hardness, is designed to absorb deformation energy from the pad portion 22, so as to prevent the deformation energy from being transmitted to the underlying elements. Therefore, the electrode structure 3 may be protected from being damaged by deformation, thereby improving the resistance against crack/peeling.

In certain embodiments, the hardness of each of the first stress buffer layer 24a and the second stress buffer layer 24b is greater than that of the first electrode metal layer 23. During the wire bonding procedure, the bonding force or pressure exerted on the pad portion 22 transmits to the stress buffer portion 21, and is distributed by the first stress buffer layer 24a, and then, is absorbed by the first electrode metal layer 23 (which is thus deformed). Such deformation energy will be further reduced by the second stress buffer layer 24b, so that the bonding performance of the electrode structure 3 may be improved by the stress buffer portion 21. The first stress buffer layer 24a has a thickness that may be the same as or different from that of the second stress buffer layer 24b, and includes a metallic material which may be the same as or different from that of the second stress buffer layer 24b. In addition, the first electrode metal layer 23 includes a metallic material which may be the same as or different from that of the pad portion 22. In certain embodiments, the first electrode metal layer 23 includes the metallic material the same as that of the pad portion 22. In certain embodiments, the first stress buffer layer 24a includes the metallic material the same as that of the second stress buffer layer 24b, and has the thickness the same as that of the second stress buffer layer 24b.

A total thickness of the stress buffer portion 21 is 0.05 to 0.5 times the total thickness of the wire bonding layered unit 20, for example, 0.05 to 0.2 times, 0.2 to 0.25 times, or 0.25 to 0.5 times. In certain embodiments, the total thickness of the stress buffer portion 21 is 0.2 to 0.25 times the total thickness of the wire bonding layered unit 20. The thickness of each of the first stress buffer layer 24a and the second stress buffer layer 24b independently may range from 300 Å and 2000 Å. The first electrode metal layer 23 has a thickness of 1 to 20 times the thickness of the first stress buffer layer 24a or the thickness of the second stress buffer layer 24b, e.g., 1 to 3 times, 3 to 7 times or 7 to 20 times. In some embodiments, the thickness of the first electrode metal layer 23 is 3 to 7 times the thickness of the first stress buffer layer 24a or the thickness of the second stress buffer layer 24b. Since the material included in the first stress buffer layer 24a or the second stress buffer layer 24b is relatively active, the thickness of the first and second stress buffer layers 24a and 24b is designed to be only a small portion of the total thickness of the wire bonding layered unit 20, so as to obtain a good overall stability of the electrode structure 3. Each of the first and second stress buffer layers 24a, 24b may independently include a harder metallic material, such as Ti, Ni, W or Cr. Thus, the stress buffer portion 21 may include e.g., Ti/Au/Ti, Ti/Al/Ti, Ti/Cu/Ti, Ti/AICu/Ti, Ni/Au/Ni, Ni/Al/Ni, Ni/Cu/Ni, Ni/AICu/Ni, W/Au/W, W/Al/W, W/AICu/W, W/Cu/W, Cr/Au/Cr, Cr/Al/Cr, Cr/Cu/Cr, Cr/AICu/Cr, Ti/Au/Ni, Ti/Al/W, Ti/Cu/Cr, Ti/AICu/Cr, Ni/Au/ Ti, Ni/Al/W, Ni/Cu/Cr or Ni/AICu/Cr.

In certain embodiments, the ohmic contact layered unit 10 includes, for example, Au, Ge, Ni, Cr, or alloys thereof, and has a thickness ranging from 500 Å to 2,000 Å.

The barrier layer 40 includes a first barrier metal layer 41 and a second barrier metal layer 42 disposed on the first barrier metal layer 41. The first barrier metal layer 41 includes a material different from that of the second barrier metal layer 42. In certain embodiments, the first barrier metal layer 41 has a thickness of 1 to 3 times a thickness of the second barrier metal layer 42. In certain embodiments, the thickness of the first barrier metal layer 41 ranges from 500 Å to 5000 Å, and the thickness of the second barrier metal layer 42 ranges from 500 Å and 2000 Å. Each of the first barrier metal layer 41 and the second barrier metal layer 42 independently includes a material such as Cr, Pt, Ti, Al, Cu, Ni, W, Au, or combinations thereof. Thus, the barrier layer 40 includes a composite material having at least two metal materials, for example, Cr/Pt, Cr/Ti, Cr/Al, Cr/Cu, Cr/Ni, Cr/W, Cr/Au, Pt/Ti, Pt/Al, Pt/Cu, Pt/Ni, Pt/W, Pt/Au, Au/Cr, Au/Ti, Au/Cu, Au/Pt, Au/Al or Au/Ni.

The adhesion layer 30 is a layer that is, in the electrode structure 3, closest to the semiconductor epitaxial structure 90 for providing an enhanced adhesion between the ohmic contact layered unit 10 and the semiconductor epitaxial structure 90. In certain embodiments, the adhesion layer 30 has a thickness ranging from 100 Å to 500 Å, and includes a material such as Au, Cr, or Rh.

LED products X1 each having a structure as shown in FIG. 1B and conventional LED products X2 were provided to inspect the products for crack/peeling. In each of the LED products X1, the second electrode 95 had a structure the same as the electrode structure 3 shown in FIG. 2. Each of the conventional LED products X2 had a structure (e.g., material and thickness) generally the same as that of the LED product X1 except that the wire bonding layered unit in each of the conventional LED products X2 had an electrode structure having only a pad portion that was the same as the pad portion 22 in the LED product X1 (i.e., without an element comparable to the stress buffer portion 21). Each of the LED products X1 and X2 further had a solder ball and a wire formed on the pad portion. The solder ball has a cross section substantially the same as that of a corresponding one of the pad portions. A shear force greater than 18.4 g (e.g., 25.28 g to 66.33 g) was applied to the solder ball. Crack or peeling between the supporting substrate and the semiconductor epitaxial structure in each of the LED products X1 and X2 were inspected, and the results are shown in Table 1. In Table 1, “cracked product” indicates that the product having the cracks or peeling between the supporting substrate and the semiconductor epitaxial structure.

TABLE 1

| LED Product | Number of Tested Product (A) | Number of Cracked Product (B) | Abnormality (B/A*100%) |
|---|---|---|---|
| X1 | 5000 | 0 | 0 |
| X2 | 5000 | 320 | 6.4 |

Referring to Table 1, under the same experimental conditions, the abnormality rate of the LED product X1 according to the present disclosure was significantly reduced. In other words, since the stress buffer portion 21 was included in the wire bonding layered unit 20, the bonding performance of the LED product was greatly improved.

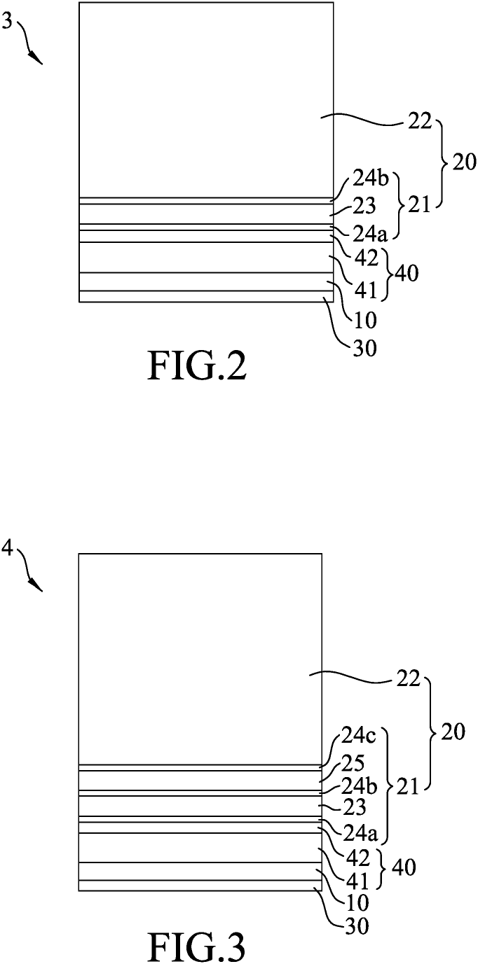

FIG. 3 is a schematic view illustrating a second embodiment of an electrode structure 4 according to the present disclosure. The electrode structure 4 has a structure similar to that of the electrode structure 3 as described above except for the stress buffer portion 21. In the electrode structure 4 shown in FIG. 3, the stress buffer portion 21 includes a first stress buffer layer 24a, a first electrode metal layer 23, a second stress buffer layer 24b, a second electrode metal layer 25, and a third stress buffer layer 24c which are stacked on one another in such order. In other words, compared to the stress buffer portion 21 of the electrode structure 3 which includes only the electrode metal layer 23 disposed between the two stress buffer layers i.e., 24a and 24b, the stress buffer portion 21 of the electrode structure 4 includes two of the electrode metal layers 23 and 25 respectively disposed between two neighboring stress buffer layers. Each of the first, second and third stress buffer layers 24a, 24b and 24c has a hardness greater than that of the pad portion 22.

The hardness of each of the first, second and third stress buffer layers 24a, 24b and 24c is greater than that of each of the first electrode metal layer 23 and the second electrode metal layer 25. In this embodiment, a structure containing the first stress buffer layer 24a, the first electrode metal layer 23, the second stress buffer layer 24b, the second electrode metal layer 25, and the third stress buffer layer 24c that are stacked on one another in such order may effectively absorb bonding energy and diminish possible deformation during wire bonding, so as to improve the reliability of the wire bonds in LEDs. The first stress buffer layer 24a, the second stress buffer layer 24b, and the third stress buffer layer 24c are identical to or different from each other in thickness and/or material. Each of the first electrode metal layer 23 and the second electrode metal layer 25 includes a metallic material which may be the same as or different from that of the pad portion 22. In certain embodiments, the material of the first electrode metal layer 23 is the same as that of the second electrode metal layer 25. In certain embodiments, the first electrode metal layer 23 has a thickness that is the same as that of the second electrode metal layer 25. In certain embodiments, the first stress buffer layer 24a, the second stress buffer layer 24b, and the third stress buffer layer 24c are made of the same material and have the same thickness.

The first stress buffer layer 24a, the second stress buffer layer 24b, and the third stress buffer layer 24c each includes a harder metallic material such as Ti, Ni, W, or Cr. Therefore, the stress buffer portion 21 may have a composite material, such as a Ti/Au/Ti/Au/Ti, Ti/Al/Ti/Al/Ti, Ti/Cu/Ti/Cu/Ti, Ti/AICu/Ti/AICu/Ti, Ni/Au/Ni/Au/Ni, Ni/Al/Ni/Al/Ni, Ni/Cu/Ni/Cu/Ni, Ni/AICu/Ni/AICu/Ni, W/Au/W/Au/W, W/Al/W/Al/W, W/AICu/W/AICu/W, W/Cu/W/Cu/W, Cr/Au/Cr/Au/Cr, Cr/Al/Cr/Al/Cr, Cr/Cu/Cr/Cu/Cr, Cr/AICu/Cr/AICu/Cr, Ti/Au/Ni/Al/Ni, Ti/Al/W/Cu/Cr, Ti/Cu/Cr/AICu/W, Ti/AICu/Cr/Cu/W, Ni/Au/Ti/Al/Ni, Ni/Al/W/Al/Cr, Ni/Cu/Cr/Cu/Cr or Ni/AICu/Cr/Au/Ti.

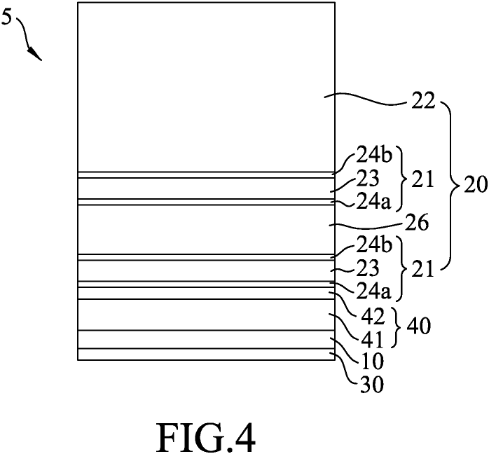

FIG. 4 is a schematic view illustrating a third embodiment of an electrode structure 5 according to the present disclosure. The electrode structure 5 has a structure similar to that of the electrode structure 3 as described above. However, in electrode structure 5, the wire bonding layered unit 20 includes at least two stress buffer portions 21 and a transition portion 26 disposed between the two stress buffer portions 21. The transition portion 26 may include a metallic material the same as that of the pad portion 22. In certain embodiments, the transition portion 26 has a thickness that is 1 to 2 times the total thickness of one stress buffer portion 21. A laminating structure containing the two stress buffer portions 21 and the transition portion 26 provides a better reinforcing structure for the LED 1, 2. The reinforcing structure may further improve performance of the electrode structure 5 in resisting against crack/peeling.

The present disclosure also provides a light-emitting device including the light-emitting diode as described above.

In conclusion, compared to the prior art, the LED according to the present disclosure is capable of successfully withstanding the bonding force or pressure exerted on the electrode structure during the wire bonding procedure by means of the stress buffer portion 21 provided in the electrode structure. Accordingly, the electrode structure of the LED according to the present disclosure provides an improved performance in resisting against crack/peeling and reducing abnormalities of the LED.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting diode, comprising:
a semiconductor epitaxial structure including a first semiconductor layer, an active layer and a second semiconductor layer arranged in such order; and
an electrode structure disposed on said semiconductor epitaxial structure and including:
an ohmic contact layered unit disposed on said semiconductor epitaxial structure, and
a wire bonding layered unit disposed on said ohmic contact layered unit, said wire bonding layered unit including at least one stress buffer portion and a pad portion disposed on said at least one stress buffer portion, said at least one stress buffer portion including a first stress buffer layer, a first electrode metal layer and a second stress buffer layer which are stacked on one another in such order on said ohmic contact layered unit, each of said first and second stress buffer layers having a hardness greater than that of said pad portion.

2. The light-emitting diode as claimed in claim 1, wherein each of said first and second stress buffer layers has a hardness greater than that of said first electrode metal layer.

3. The light-emitting diode as claimed in claim 1, wherein said first electrode metal layer includes a metallic material the same as that of said pad portion.

4. The light-emitting diode as claimed in claim 1, wherein said first stress buffer layer includes a metallic material the same as that of said second stress buffer layer.

5. The light-emitting diode as claimed in claim 1, wherein said first stress buffer layer has a thickness the same as that of said second stress buffer layer.

6. The light-emitting diode as claimed in claim 1, wherein said first stress buffer layer includes a metallic material different from that of said second stress buffer layer.

7. The light-emitting diode as claimed in claim 1, wherein said first stress buffer layer has a thickness different from that of said second stress buffer layer.

8. The light-emitting diode as claimed in claim 1, wherein said at least one stress buffer portion further includes a second electrode metal layer disposed on said second stress buffer layer, and a third stress buffer layer disposed on said second electrode metal layer.

9. The light-emitting diode as claimed in claim 8, wherein said third stress buffer layer has a hardness greater than that of each of said pad portion and said second electrode metal layer.

10. The light-emitting diode as claimed in claim 1, wherein said at least one stress buffer portion of said wire bonding layered unit includes at least two stress buffer portions, and said wire bonding layered unit further includes a transition portion disposed between said at least two stress buffer portions, said transition portion including a metallic material the same as that of said pad portion.

11. The light-emitting diode as claimed in claim 1, wherein a total thickness of said stress buffer portion is 0.05 to 0.5 times a total thickness of said wire bonding layered unit .

12. The light-emitting diode as claimed in claim 1, wherein said first electrode metal layer has a thickness of 1 to 20 times a thickness of said first stress burrier layer.

13. The light-emitting diode as claimed in claim 1, wherein each of said first and second stress buffer layers independently has a thickness ranging from 300 Å to 2000 Å.

14. The light-emitting diode as claimed in claim 1, wherein each of said first and second stress buffer layers independently includes titanium (Ti), nickel (Ni), tungsten (W), or chromium (Cr).

15. The light-emitting diode as claimed in claim 1, wherein said pad portion includes gold (Au), aluminum (Al), copper (Cu), or alloys thereof.

16. The light-emitting diode as claimed in claim 1, wherein said wire bonding layered unit of said electrode structures has a thickness of 0.55 to 0.97 times a total thickness of said electrode structures.

17. The light-emitting diode as claimed in claim 1, wherein said wire bonding layered unit has a thickness ranging from 10000 Å to 40000 Å.

18. The light-emitting diode as claimed in claim 1, wherein said ohmic contact layered unit has a thickness ranging from 500 Å to 2000 Å.

19. The light-emitting diode as claimed in claim 1, wherein said light-emitting diode is configured to emit a light having a wavelength ranging from 550 nm to 950 nm.

20. A light-emitting device, comprising:
at least one said light-emitting diode as claimed in claim 1.
